(19) United States
(12) Patent Application Publication
(10) Pub. No.: US 2024/0291221 A1
(43) Pub. Date: Aug. 29, 2024

(54) STACKABLE COOLING DEVICE FOR HIGH POWER FIBER LASER COOLING

(71) Applicant: Technology Innovation Institute- Sole Proprietorship LLC, Masdar City, Abu Dhabi (AE)

(72) Inventor: Jawaher Mohammed Harbi Yazreb AlAmeri, MBZ City, Abu Dhabi (AE)

(73) Assignee: Technology Innovation Institute- Sole Proprietorship LLC, Masdar City, Abu Dhabi (AE)

(21) Appl. No.: 18/587,435

(22) Filed: Feb. 26, 2024

Related U.S. Application Data
(60) Provisional application No. 63/487,379, filed on Feb. 28, 2023.

(51) Int. Cl. H01S 3/04; H01S 3/067; H01S 3/094

(52) U.S. Cl. CPC H01S 3/0407; H01S 3/06708; H01S 3/094003

(57) ABSTRACT

The present disclosure describes a cooling device that may be configured to hold and cool an optical fiber, such as an optical fiber for a fiber laser. The cooling device of the present disclosure may include an active cooling unit having a base portion, one or multiple intermediate portions, and a top portion with a continuous internal channel configured to contain fluid for active cooling, and may further include a passive cooling unit nested within the intermediate portion. The cooling device includes a stackable, modular design that can be easily customized to accommodate different fiber lengths and diameters.

### CROSS-REFERENCE TO RELATED APPLICATIONS

This application claims the benefit of U.S. Provisional Application No. 63/487,379 filed on Feb. 28, 2023, which is hereby incorporated by reference in its entirety.

### FIELD

The present disclosure relates generally to a cooling device. More specifically, the present disclosure relates to a stackable cooling device for cooling a fiber laser during laser operation.

### BACKGROUND

Fiber laser systems are employed in numerous fields such as medicine, defense, research, and industry. Large-mode area fibers permit high power to be transmitted through the fiber without damage. However, fibers for high powered lasers are typically coated with materials such as fluoroacrylates, which have limited heat resistance, on the order of 150° C. to 200° C. As fiber lasers can generate excess heat as a waste product during operation, it is often necessary to maintain an operating temperature of approximately 80° C. or below to ensure the long-term reliability of these coated fibers.

In an effort to take advantage of high laser pumping power while maintaining fiber lifetime, fiber laser systems utilize cooling systems to cool the fiber. Currently available cooling systems include solid or hollow spools which may utilize water cooling in the base of the system, which offers limited cooling capacity. Particularly in the case of solid spools, which are heavier and have lower surface area to volume ratios, the cooling power of such devices is limited and often requires long stabilization times to reach the desired operational temperature.

There remains a need for cooling devices for optical fibers which provide reliable and uniform cooling. Additionally, there is a need for cooling devices which can accommodate optical fibers of different lengths and diameters, instead of requiring a new device for each type of fiber. The present disclosure explores a modular device that combines active and passive cooling units for improved cooling capacity coupled with a customizable design.

### SUMMARY

In one aspect, the present disclosure relates to a cooling device, including: an active cooling unit, including: a base portion including at least one base inlet, at least one base outlet, and an internal channel, a first intermediate portion including an outer surface with grooved indentations, a hollow core, at least one intermediate inlet, at least one intermediate outlet, and an internal channel, wherein the first intermediate portion is stackable, a top portion including a hollow core, at least one top inlet, at least one top outlet, and an internal channel connected to the at least one top inlet and the at least one top outlet, wherein the internal channels of the base portion, the first intermediate portion, and the top portion are in fluid communication to form a continuous internal channel configured to contain fluid, wherein the base portion, the first intermediate portion, and the top portion are separable and are connected by the continuous internal channel, and a passive cooling unit fitted within the hollow core of the first intermediate portion.

In embodiments of this aspect, the active cooling unit of the disclosed cooling device includes aluminum, copper, chromium, cobalt, gold, iridium, magnesium, molybdenum, rhodium, silicon, silver, sodium, tungsten, zinc, or combinations or alloys thereof.

In embodiments of this aspect, the disclosed continuous internal channel according to any one of the above example embodiments can be coated with an anti-corrosive material.

In embodiments of this aspect, the disclosed active cooling unit according to any one of the above example embodiments further includes a second intermediate portion including an outer surface with grooved indentations, a hollow core, at least one intermediate inlet, at least one intermediate outlet, and an internal channel, wherein the first intermediate portion and the second intermediate portion are stacked such that the internal channel of the first intermediate portion is in fluid communication with the internal channel of the second intermediate portion.

In embodiments of this aspect, the disclosed cooling device according to any one of the above example embodiments can further include a second passive cooling unit fitted within the hollow core of the second intermediate portion.

In embodiments of this aspect, and according to any one of the above example embodiments, the base portion, the first intermediate portion, and the top portion each include raised features and depressed features that are configured to be nested when the base portion, the first intermediate portion, and the top portion are stacked, such that there is a hermetic seal between each of the base portion, the first intermediate portion, and the top portion.

In embodiments of this aspect, the disclosed grooved indentations according to any one of the above example embodiments are configured to hold an optical fiber wound around the first intermediate portion.

In embodiments of this aspect, and according to any one of the above example embodiments, the at least one base inlet and the at least one base outlet are each connected to a manifold, a chiller, or combinations thereof.

In embodiments of this aspect, the disclosed cooling device according to any one of the above example embodiments can further include at least one pipe connecting the top inlet to the top outlet.

In embodiments of this aspect, and according to any one of the above example embodiments, the disclosed at least one pipe includes brass, copper, zinc, titanium, nickel, silicon, rubber, plastic, or combinations thereof.

In embodiments of this aspect, and according to any one of the above example embodiments, the disclosed continuous internal channel is straight, curved, S-shaped, branched, or angular.

In embodiments of this aspect, and according to any one of the above example embodiments, the disclosed continuous internal channel is configured to provide direct contact between the active cooling unit and a cooling fluid.

In embodiments of this aspect, the disclosed passive cooling unit according to any one of the above example embodiments includes a conventional heatsink pattern, a topology-optimized generative design pattern, or a fractal pattern.

In embodiments of this aspect, and according to any one of the above example embodiments, the disclosed passive cooling unit includes aluminum, copper, chromium, cobalt, gold, iridium, magnesium, molybdenum, rhodium, silicon, silver, sodium, tungsten, zinc, or combinations thereof.

In embodiments of this aspect, the disclosed cooling device according to any one of the above example embodiments maintains a temperature of less than about 50° C. at a pumping power of 10 kW.

Another aspect of the present disclosure relates to a method of cooling an optical fiber, including: providing a cooling device which includes: a base portion including at least one base inlet, at least one base outlet, and an internal channel, a first intermediate portion including an outer surface with grooved indentations configured to hold the optical fiber, a hollow core, at least one intermediate inlet, at least one intermediate outlet, and an internal channel, wherein the first intermediate portion is stackable, a top portion including a hollow core, at least one top inlet, at least one top outlet, and an internal channel, wherein the internal channels of the base portion, the first intermediate portion, and the top portion are in fluid communication to form a continuous internal channel configured to contain fluid, wherein the base portion, the first intermediate portion, and the top portion are separable and are connected by the continuous internal channel, and a passive cooling unit fitted within the hollow core of the first intermediate portion, applying a pumping power to the optical fiber, and passing a cooling fluid through the continuous internal channel, thereby cooling the optical fiber.

In embodiments of this aspect, the disclosed cooling fluid can include water, glycol, oils, artificial cooling fluids, or combinations thereof.

In embodiments of this aspect, the disclosed cooling fluid according to any one of the above example embodiments is in direct contact with the cooling device.

In embodiments of this aspect, the disclosed continuous internal channel according to any one of the above example embodiments is coated with an anti-corrosive material.

In embodiments of this aspect, the disclosed cooling device according to any one of the above example embodiments further includes a second intermediate portion including an outer surface with grooved indentations, a hollow core, at least one intermediate inlet, at least one intermediate outlet, and an internal channel, wherein the first intermediate portion and the second intermediate portion are stacked such that the internal channel of the first intermediate portion is in fluid communication with the internal channel of the second intermediate portion.

In embodiments of this aspect, the disclosed cooling device according to any one of the above example embodiments further includes a second passive cooling unit fitted within the hollow core of the second intermediate portion.

In embodiments of this aspect, and according to any one of the above example embodiments, the base portion, the first intermediate portion, and the top portion each include raised features and depressed features that are configured to be nested when the base portion, the first intermediate portion, and the top portion are stacked.

In embodiments of this aspect, the disclosed cooling device according to any one of the above example embodiments maintains a temperature of less than about 50° C. at a pumping power of 10 kW.

Another aspect of the present disclosure relates to a fiber laser system with integrated cooling, including: an optical fiber wound around a cooling device which includes: a base portion including at least one base inlet, at least one base outlet, and an internal channel, a first intermediate portion including an outer surface with grooved indentations configured to hold the optical fiber, a hollow core, at least one intermediate inlet, at least one intermediate outlet, and an internal channel, wherein the first intermediate portion is stackable, a top portion including a hollow core, at least one top inlet, at least one top outlet, and an internal channel, wherein the internal channels of the base portion, the first intermediate portion, and the top portion are in fluid communication to form a continuous internal channel configured to contain fluid, wherein the base portion, the first intermediate portion, and the top portion are separable and are connected by the continuous internal channel, and a passive cooling unit fitted within the hollow core of the first intermediate portion, a manifold for providing a cooling fluid to the cooling device, and a power source for providing power to the optical fiber.

In embodiments of this aspect, the disclosed cooling fluid is in direct contact with the cooling device.

In embodiments of this aspect, the disclosed continuous internal channel according to any one of the above example embodiments is coated with an anti-corrosive material.

In embodiments of this aspect, the disclosed cooling device according to any one of the above example embodiments further includes a second intermediate portion including an outer surface with grooved indentations, a hollow core, at least one intermediate inlet, at least one intermediate outlet, and an internal channel, wherein the first intermediate portion and the second intermediate portion are stacked such that the internal channel of the first intermediate portion is in fluid communication with the internal channel of the second intermediate portion.

In embodiments of this aspect, the disclosed cooling device according to any one of the above example embodiments further includes a second passive cooling unit fitted within the hollow core of the second intermediate portion.

In embodiments of this aspect, and according to any one of the above example embodiments, the base portion, the first intermediate portion, and the top portion each include raised features and depressed features that are configured to be nested when the base portion, the first intermediate portion, and the top portion are stacked.

In embodiments of this aspect, the disclosed cooling device according to any one of the above example embodiments maintains a temperature of less than about 50° C. at a pumping power of 10 kW.

### DRAWINGS

Aspects, features, benefits, and advantages of the embodiments described herein will be apparent with regard to the following description, appended claims, and accompanying drawings where:

FIG. 1 is an illustrative diagram of a cooling device, according to an embodiment of the present disclosure.

FIG. 2 is an illustrative diagram of a cooling device having multiple intermediate portions, according to an embodiment of the present disclosure.

FIG. 3 is an illustrative diagram of an exploded view of a cooling device, according to an embodiment of the present disclosure.

FIG. 4 is a flow chart of a method of cooling an optical fiber, according to an embodiment of the present disclosure.

FIG. 5 is a graph of pumping power vs. maximum temperature, according to an embodiment of the present disclosure.

### DETAILED DESCRIPTION

The present disclosure describes a cooling device with stackable, modular components, configured to hold and cool an optical fiber. The cooling device of the present disclosure can be configured to hold fibers of different lengths and diameters by adding or switching out components. Using a combination of active and passive cooling, the present device provides excellent heat dispersion and is capable of maintaining a temperature of less than about 50° C. at a pumping power of 10 kW. The cooling device of the present disclosure features an internal channel through the device through which a cooling fluid may be passed, such that the cooling fluid is in direct contact with the cooling device. The features and design of the cooling device of the present disclosure allow for improved cooling performance over presently available devices, and the modular design allows cooling of optical fibers of different lengths, since a longer fiber could be easily accommodated by adding an additional component to the cooling device of the present disclosure, rather than needing to obtain a different device of a larger size. Similarly, optical fibers of different diameters may be accommodated by changing out the portion of the device that holds the optical fiber, while the rest of the device is compatible with any size fiber.

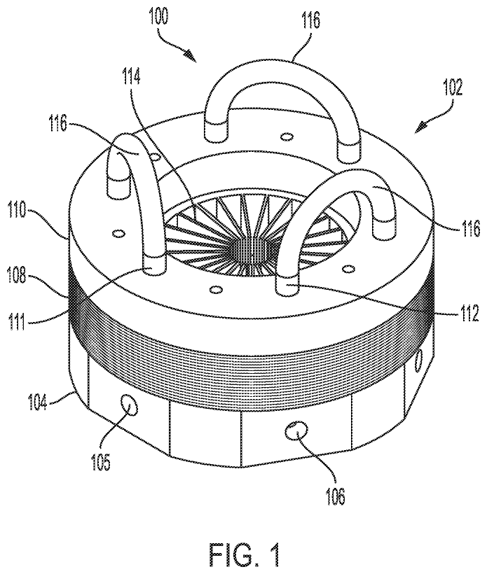

In embodiments, there is provided a cooling device. FIG. 1 is an illustrative diagram of a cooling device, according to an embodiment of the present disclosure. The cooling device 100 may include an active cooling unit 102, which in embodiments includes a base portion 104, a first intermediate portion 108, and a top portion 110. The cooling device may include a continuous internal channel which runs through the base portion, the intermediate portion, and the top portion and which is configured to contain fluid. The cooling device 100 may further include a passive cooling unit 114, such that in embodiments the cooling device 100 includes both the active cooling unit 102 and the passive cooling unit 114. The size of the cooling device 100 is not particularly limited and may be adjusted to accommodate the size of the fiber that needs to be cooled. For example, when cooling a fiber with a length of about 10 m, the cooling device 100 may have a total height of about 5 cm to about 10 cm and a circumference of about 0.2 m to about 0.8 m, such as a total height of about 5 cm, about 6 cm, about 7 cm, about 8 cm, about 9 cm, about 10 cm, or any value contained within a range formed by any two of the preceding values, and a circumference of about 0.2 m, about 0.3 m, about 0.4 m, about 0.5 m, about 0.6 m, about 0.7 m, about 0.8 m, or any value contained within a range formed by any two of the preceding values. It is contemplated that the cooling device 100 may have different dimensions when configured to cool a fiber of a different length.

The active cooling unit 102 and its components may be formed from aluminum, copper, chromium, cobalt, gold, iridium, magnesium, molybdenum, rhodium, silicon, silver, sodium, tungsten, zinc, or combinations or alloys thereof. Each of the components of the cooling device may be formed from the same material or different materials, according to embodiments of the present disclosure.

In embodiments, the base portion 104 includes at least one base inlet 105, at least one base outlet 106, and an internal channel. The base portion may include multiple inlets and outlets, such as two inlets and two outlets, three inlets and three outlets, four inlets and four outlets, five inlets and five outlets, and so forth. The at least one base inlet and the at least one base outlet may be connected to the internal channel of the base portion, and in embodiments are connected to each other via the internal channel of the base portion. The at least one base inlet and the at least one base outlet may be connected to a manifold, a chiller, or other source for providing fluid, such that fluid flowing from the manifold enters the at least one base inlet and flows into the internal channel. The size of the base portion 104 is not particularly limited and may be adjusted to suit the needs of a user of the cooling device. The base portion may be circular, triangular, square, pentagonal, hexagonal, heptagonal, octagonal, or other polyhedral shape.

In embodiments, the first intermediate portion 108 includes an outer surface with grooved indentations, a hollow core, at least one intermediate inlet, at least one intermediate outlet, and an internal channel. The outer surface with grooved indentations may be configured to hold an optical fiber such that the optical fiber is nested within the grooves. The grooved indentations may be in the shape of a half circle or U-shape. The size of the grooved indentations is not particularly limited and may be selected based on the size of the optical fiber to be held. In embodiments, the first intermediate portion is stackable, such that the first intermediate portion may be configured to stack on top of the base portion. The internal channel of the first intermediate portion is, in embodiments, connected to and in fluid communication with the internal channel of the base portion.

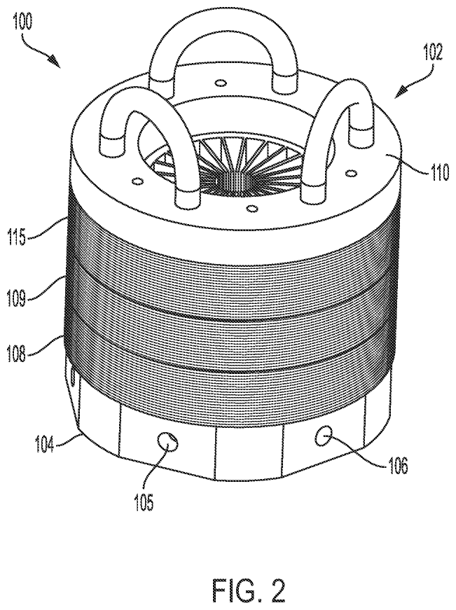

In embodiments, the active cooling unit 102 includes multiple intermediate portions. The active cooling unit may include one, two, three, four, five, or six intermediate portions. It is contemplated that more than six intermediate portions may be included in the active cooling unit when a large length of fiber needs to be cooled. FIG. 2 is an illustrative diagram of a cooling device 100 which includes an active cooling unit 102 having multiple intermediate portions, according to an embodiment of the present disclosure. For example, the active cooling unit can in embodiments include a second intermediate portion 109 which includes an outer surface with grooved indentations, a hollow core, at least one intermediate inlet, at least one intermediate outlet, and an internal channel, wherein the first intermediate portion and the second intermediate portion are stacked such that the internal channel of the first intermediate portion is in fluid communication with the internal channel of the second intermediate portion. The active cooling unit 102 may further include a third intermediate portion 115 which includes an outer surface with grooved indentations, a hollow core, at least one intermediate inlet, at least one intermediate outlet, and an internal channel, wherein the first intermediate portion, the second intermediate portion, and the third intermediate portion are stacked such that the internal channels of the first intermediate portion, the second intermediate portion, and the third intermediate portion are in fluid communication. The active cooling unit may include one, two, three, four, five, or six intermediate portions. The number of intermediate portions included in the active cooling unit is not particularly limited and it is contemplated that more than six intermediate portions could be included in the active cooling unit, in embodiments of the present disclosure.

In embodiments, the grooved indentations of the intermediate portion are configured to hold an optical fiber. It is contemplated that additional intermediate portions could be added to accommodate a longer optical fiber, or that intermediate portions could be removed to accommodate a shorter optical fiber. In embodiments, the intermediate portion can be switched out for an intermediate portion having differently sized grooved indentations, such that an optical fiber of a different diameter could be accommodated.

In embodiments, the cooling device 100 includes a passive cooling unit 114 fitted within the hollow core of the first intermediate portion of the active cooling unit. In embodiments where the cooling device includes an active cooling unit having multiple intermediate portions, the cooling device may further include multiple passive cooling units nested within the hollow cores of each intermediate portion. It is contemplated that in embodiments having multiple intermediate portions, one, some, or all of the intermediate portions may have a passive cooling unit nested within the hollow core. For example, a cooling device with an active cooling unit having three intermediate portions may include one, two, or three passive cooling units. The passive cooling unit 114 may include a conventional heatsink pattern, a topology-optimized generative design pattern, or a fractal pattern. In embodiments, the passive cooling unit is formed from aluminum, copper, chromium, cobalt, gold, iridium, magnesium, molybdenum, rhodium, silicon, silver, sodium, tungsten, zinc, or combinations or alloys thereof. In embodiments which include multiple passive cooling units, each passive cooling unit may be formed from the same material or a different material and may include the same design or a different design.

In embodiments, the active cooling unit includes a top portion 110. The top portion 110 may include a hollow core, at least one top inlet 111, at least one top outlet 112, and an internal channel. The top portion may, optionally, include pipes 116 which are outside of the top portion. The pipes 116 may be connected to the at least one top inlet 111 and the at least one top outlet 112. The pipes 116 may be formed from brass, copper, aluminum, zinc, titanium, nickel, silicon, rubber, plastic, or combinations or alloys thereof. In embodiments, the pipes are omitted, such that the cooling device 100 does not include pipes. In such embodiments where pipes are not included, the internal channel of the top portion may connect the at least one top inlet to the at least one top outlet, such that the internal channel of the top portion is completely contained within the top portion.

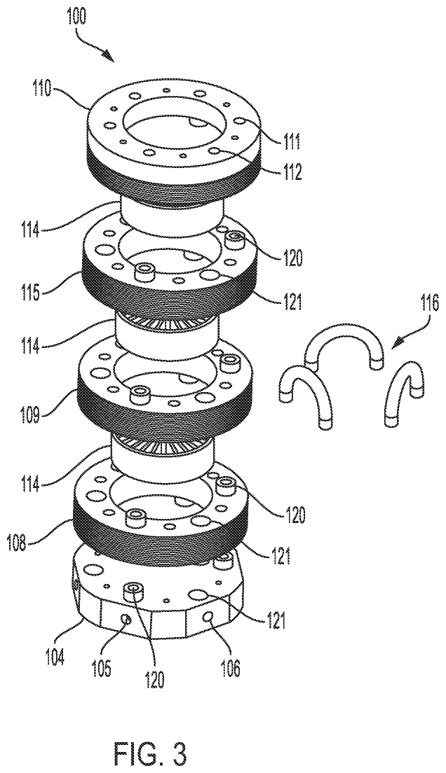

In embodiments, the base portion, the first intermediate portion, and the top portion include raised features and depressed features. In embodiments which include multiple intermediate portions, each intermediate portion may include these raised features and depressed features as described herein. FIG. 3 is an illustrative diagram of an exploded view of a cooling device, according to an embodiment of the present disclosure. Each portion of the active cooling unit, i.e., the base portion, the first intermediate portion (and any addition intermediate portions), and the top portion, may include raised features 120 and depressed features 121 that are configured to interlock when the base portion, the first intermediate portion, and the top portion are stacked, such that there is a hermetic seal between each of the base portion, the first intermediate portion, and the top portion. For example, each portion of the active cooling unit may include a raised feature 120 which may be a male connector and a depressed feature 121 which may be a female connector. Each portion of the active cooling unit may include one or multiple such raised features and depressed features. It is contemplated that when the portions of the device are stacked, each of the raised features and depressed features are nested and therefore interlock, such that the active cooling unit is securely stacked. For example, the raised features of the base portion interlock into the depressed features of the first intermediate portion, and so forth. In embodiments, the internal channels of each of the base portion, the first intermediate portion (and any additional intermediate portions, if present), and the top portion pass through each of the raised features and depressed features, such that, when stacked, each of the internal channels of the base portion, the first intermediate portion (and any additional intermediate portions, if present), and the top portion are connected with a hermetic seal. In embodiments, an additional sealant material (including but not limited to polytetrafluoroethylene, polyurethane, or other sealant materials known to those skilled in art) is used when stacking the components of the active cooling unit to ensure a secure seal between each component. In embodiments, no additional sealant is used, and the raised features and depressed features provide a hermetic seal between the components of the active cooling unit.

In embodiments, the internal channels of the base portion, the first intermediate portion, and the top portion are in fluid communication to form a continuous internal channel configured to contain fluid. The continuous internal channel may be straight, curved, S-shaped, branched, or angular. In embodiments, the continuous internal channel may be a combination of shapes, such that the continuous internal channel is, for example, straight in one region and curved in another region. It is contemplated that a fluid may enter the cooling device via a base inlet and travel through the continuous internal channel, thus traversing each of the base portion, the first intermediate portion (and any additional intermediate portions, in embodiments where additional intermediate portions are included), and the top portion. The fluid enters the top portion via the at least one top inlet, and then may travel through pipes which are fixed to the top portion, in embodiments where pipes are included, and subsequently return to the top portion through the pipes to travel through the at least one top outlet to the continuous internal channel, and exit the active cooling unit via a base outlet. In embodiments where pipes are not included, the fluid travels through the internal channel of the top portion from the at least one top inlet to the at least one top outlet, and then travels through the continuous internal channel and exits the active cooling unit via the base outlet. It is contemplated that the continuous internal channel may be a loop, such that fluid travels from a manifold or chiller which is connected to the base inlet, through the continuous internal channel which runs through the components of the active cooling unit, exits via the base outlet, and returns to the manifold or chiller. In embodiments which include multiple inlets and outlets and thus each portion of the active cooling unit includes multiple internal channels, these internal channels may be connected to form one continuous internal channel that functions as a single fluid loop, or there may be multiple continuous internal channels that each function as a separate fluid loop.

In embodiments, the continuous internal channel is configured to provide direct contact between the active cooling unit and a fluid, such as a cooling fluid. For example, the continuous internal channel may be directly machined through the active cooling unit and does not contain separate pipes, fixtures, or other components. This direct contact of the fluid with the active cooling unit can, in embodiments, lead to improved cooling capacity, without wishing to be bound by theory.

In embodiments, the continuous internal channel is coated with an anti-corrosive material, including but not limited to anti-corrosive metals, polymers such as polyepoxides and/or polyurethane, nanocomposites of polymers and graphene, or any other anti-corrosive material known to those skilled in the art. In embodiments, the continuous internal channel has been subjected to a surface treatment to reduce corrosion, including but not limited to anodization, plasma electrolytic oxidation, or other methods familiar to those skilled in the art. The anti-corrosive material or surface treatment is not particularly limited and may be selected by a user of the cooling device of the present disclosure.

The cooling device of the present disclosure may include any or all of the features described herein. The embodiments described herein may be combined in any fashion to produce additional embodiments.

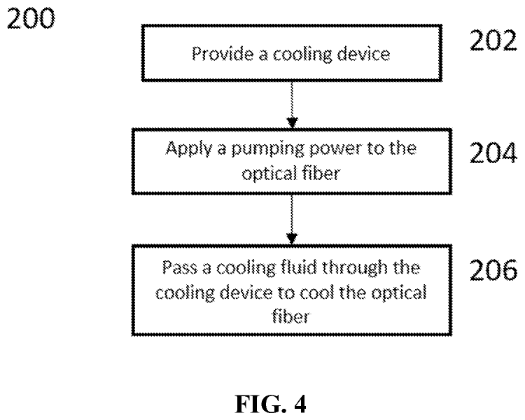

In embodiments, there is provided a method of cooling an optical fiber. The method may include providing a cooling device as described herein, such as a cooling device including an active cooling unit having a base portion including at least one base inlet, at least one base outlet, and an internal channel; a first intermediate portion including an outer surface with grooved indentations configured to hold the optical fiber, a hollow core, at least one intermediate inlet, at least one intermediate outlet, and an internal channel, wherein the first intermediate portion is stackable; a top portion including a hollow core, at least one top inlet, at least one top outlet, and an internal channel; wherein the internal channels of the base portion, the first intermediate portion, and the top portion are in fluid communication to form a continuous internal channel configured to contain fluid; wherein the base portion, the first intermediate portion, and the top portion are separable and are connected by the continuous internal channel; and a passive cooling unit fitted within the hollow core of the intermediate portion. The method may include applying a pumping power to the optical fiber which may be wrapped or wound around the cooling device and passing a cooling fluid through the continuous internal channel, thereby cooling the optical fiber. FIG. 4 is a flow chart of a method of cooling an optical fiber, according to an embodiment of the present disclosure.

In embodiments, the method 200 includes providing a cooling device 202. The cooling device may be a cooling device as described herein, according to any embodiment or combination of embodiments. The optical fiber may be wrapped or wound around the cooling device such that the optical fiber is securely held.

In embodiments, the method 200 includes a step of applying a pumping power to the optical fiber 204. As will be familiar to those skilled in the art, operation of a fiber laser includes application of a pumping power to initiate laser operation. The components of the fiber laser, beyond the cooling device described herein, are not particularly limited and may be selected by a user of the cooling device of the present disclosure.

In embodiments, the method 200 includes passing a cooling fluid through the cooling device 206, thereby cooling the optical fiber. In embodiments, the steps of applying a pumping power 204 and passing a cooling fluid through the cooling device 206 are performed simultaneously, and in embodiments, these steps are performed sequentially. In embodiments, there is included a manifold, a chiller, or combinations thereof in connection with the cooling device to provide the cooling fluid. The cooling fluid may include water, glycol, oils, artificial cooling fluids, or combinations thereof. In embodiments, the cooling fluid includes but is not limited to water, deionized water, distilled water, mineral oil, glycol, fluorinated olefins, perfluoroaminoolefins, polyalphaolefins, hydrofluoroethers, perfluoropolyethers, the like, or combinations thereof.

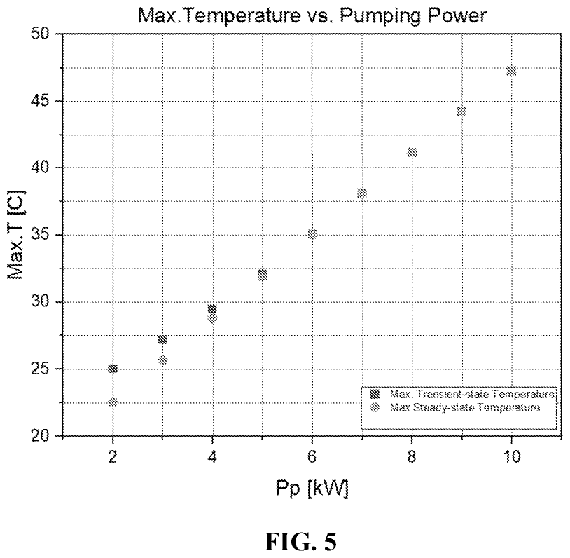

In embodiments, the cooling device maintains a temperature of less than about 50° C. at a pumping power of 10 kW. For example, the cooling device may maintain a temperature of less than about 50° C., less than about 45° C., less than about 40° C., less than about 35° C., less than about 30° C., less than about 25° C., less than about 20° C., less than about 15° C., less than about 10° C., less than about 5° C., less than about 0° C., or any value contained within a range formed by any two of the preceding values. FIG. 5 is a graph of pumping power vs. maximum temperature, according to an embodiment of the present disclosure. As shown in FIG. 5, when applying a pumping power of 10 kW or less, the temperature of the cooling device was consistently below 50° C. It is contemplated that when applying a pumping power above 10 KW, the cooling device will maintain a temperature that is proportional to the ratio described herein; i.e., at a pumping power of 20 kW, the cooling device of the present disclosure may maintain a temperature of less than about 100° C., without wishing to be bound by theory. Thermal analysis of the cooling device may be performed using any temperature measurement tool known to those skilled in the art, including but not limited to traditional temperature measurement and/or thermal modeling using finite element analysis tools (e.g., Ansys) and other measurement tools.

In embodiments, there is provided a fiber laser system with integrated cooling, which may include a cooling device according to any embodiment or combination of embodiments as described herein. For example, the fiber laser system with integrated cooling may include an optical fiber wound around a cooling device which includes a base portion which has at least one base inlet, at least one base outlet, and an internal channel, a first intermediate portion which has an outer surface with grooved indentations configured to hold the optical fiber, a hollow core, at least one intermediate inlet, at least one intermediate outlet, and an internal channel, wherein the first intermediate portion is stackable, a top portion which has a hollow core, at least one top inlet, at least one top outlet, and an internal channel, wherein the internal channels of the base portion, the first intermediate portion, and the top portion are in fluid communication to form a continuous internal channel configured to contain fluid, wherein the base portion, the first intermediate portion, and the top portion are separable and are connected by the continuous internal channel, and a passive cooling unit fitted within the hollow core of the intermediate portion, a manifold for providing a cooling fluid to the cooling device, and a power source for providing power to the optical fiber.

The manifold for providing a cooling fluid to the cooling device is not particularly limited and may be any manifold, chiller, reservoir, or fluid source known to those skilled in the art. Similarly, the power source for providing power to the optical fiber is not limited and may be selected according to the needs of a user of the fiber laser system.

### Examples

The cooling capacity of several devices was evaluated and compared to the cooling capacity of the device of the present disclosure. Exemplary cooling devices were prepared from aluminum with a height of approximately 8-9 cm and a circumference of approximately 0.5 m, with grooves of 550 μm configured to hold an optical fiber. The cooling devices of this size were capable of accommodating 10 m of optical fiber length. TABLE 1 shows the equilibrium temperature and time to reach equilibrium temperature at a pumping power of 10 kW. The finite element analysis tool Ansys was used to model the equilibrium temperatures described herein.

TABLE 1

| | | | Time to Reach |
|---|---|---|---|
| | | Equilibrium | Equilibrium |
| | Pumping Power | Temperature | Temperature |
| | (kW) | (° C.) | (min) |
| Solid spool | 10 | 76.60 | 19.15 |
| Hollow spool | 10 | 88.24 | 24.13 |
| Hollow spool with | 10 | 79.95 | 14.66 |
| passive cooling | | | |
| Present design with | 10 | 47.27 | 40.84 |
| combined active and | | | |
| passive cooling | | | |

As shown in TABLE 1, the cooling device of the present disclosure maintains a significantly lower temperature than conventional cooling device designs, with an equilibrium temperature of less than 50° C., compared to temperatures of 76-88° C. from other cooling devices. The present device offers a marked improvement over currently available technologies, with the added advantage of a stackable design which can readily be altered to accommodate different optical fiber lengths and diameters.

This disclosure is not limited to the particular systems, devices and methods described, as these may vary. The terminology used in the description is for the purpose of describing the particular versions or embodiments only and is not intended to limit the scope.

As used in this document, the singular forms “a,” “an,” and “the” include plural references unless the context clearly dictates otherwise. Unless defined otherwise, all technical and scientific terms used herein have the same meanings as commonly understood by one of ordinary skill in the art. Nothing in this disclosure is to be construed as an admission that the embodiments described in this disclosure are not entitled to antedate such disclosure by virtue of prior invention. As used in this document, the term “comprising” means “including, but not limited to.”

As used herein, the term “about” means plus or minus 10% of the numerical value of the number with which it is being used. For example, “about 50%” means in the range of 45-55%. Any value modified by “about” as used herein therefore discloses both the range described above and the exact value. For example, “about 50%” includes exactly 50% as well as the range of 45-55%, as described herein.

In the above detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” et cetera). While various compositions, methods, and devices are described in terms of “comprising” various components or steps (interpreted as meaning “including, but not limited to”), the compositions, methods, and devices can also “consist essentially of” or “consist of” the various components and steps, and such terminology should be interpreted as defining essentially closed-member groups. It will be further understood by those within the art that if a specific number of an introduced claim recitation is intended, such an intent will be explicitly recited in the claim, and in the absence of such recitation no such intent is present.

For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations). Furthermore, in those instances where a convention analogous to “at least one of A, B, and C, et cetera” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, et cetera). In those instances where a convention analogous to “at least one of A, B, or C, et cetera” is used, in general such a construction is intended in the sense one having skill in the art would understand the convention (for example, “a system having at least one of A, B, or C” would include but not be limited to systems that have A alone, B alone, C alone, A and B together, A and C together, B and C together, and/or A, B, and C together, et cetera). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, et cetera. As a non-limiting example, each range discussed herein can be readily broken down into a lower third, middle third and upper third, et cetera. As will also be understood by one skilled in the art all language such as “up to,” “at least,” and the like include the number recited and refer to ranges that can be subsequently broken down into subranges as discussed above. Finally, as will be understood by one skilled in the art, a range includes each individual member. Thus, for example, a group having 1-3 compounds refers to groups having 1, 2, or 3 compounds. Similarly, a group having 1-5 cells refers to groups having 1, 2, 3, 4, or 5 compounds, and so forth.

Various of the above-disclosed and other features and functions, or alternatives thereof, may be combined into many other different systems or applications. Various presently unforeseen or unanticipated alternatives, modifications, variations, or improvements therein may be subsequently made by those skilled in the art, each of which is also intended to be encompassed by the disclosed embodiments.

### EMBODIMENTS

What is claimed is:

1. A cooling device, comprising:
an active cooling unit, comprising:
a base portion comprising at least one base inlet, at least one base outlet, and an internal channel,
a first intermediate portion comprising an outer surface with grooved indentations, a hollow core, at least one intermediate inlet, at least one intermediate outlet, and an internal channel, wherein the first intermediate portion is stackable,
a top portion comprising a hollow core, at least one top inlet, at least one top outlet, and an internal channel connected to the at least one top inlet and the at least one top outlet,
wherein the internal channels of the base portion, the first intermediate portion, and the top portion are in fluid communication to form a continuous internal channel configured to contain fluid,
wherein the base portion, the first intermediate portion, and the top portion are separable and are connected by the continuous internal channel, and
a passive cooling unit fitted within the hollow core of the first intermediate portion.

2. The cooling device of claim 1, wherein the active cooling unit comprises aluminum, copper, chromium, cobalt, gold, iridium, magnesium, molybdenum, rhodium, silicon, silver, sodium, tungsten, zinc, or combinations or alloys thereof.

3. The cooling device of claim 1, wherein the continuous internal channel is coated with an anti-corrosive material.

4. The cooling device of claim 1, wherein the active cooling unit further comprises a second intermediate portion comprising an outer surface with grooved indentations, a hollow core, at least one intermediate inlet, at least one intermediate outlet, and an internal channel, wherein the first intermediate portion and the second intermediate portion are stacked such that the internal channel of the first intermediate portion is in fluid communication with the internal channel of the second intermediate portion.

5. The cooling device of claim 4, further comprising a second passive cooling unit fitted within the hollow core of the second intermediate portion.

6. The cooling device of claim 1, wherein the base portion, the first intermediate portion, and the top portion each comprise raised features and depressed features that are configured to interlock when the base portion, the first intermediate portion, and the top portion are stacked, such that there is a hermetic seal between each of the base portion, the first intermediate portion, and the top portion.

7. The cooling device of claim 1, wherein the grooved indentations are configured to hold an optical fiber wound around the first intermediate portion.

8. The cooling device of claim 1, wherein the at least one base inlet and the at least one base outlet are each connected to a manifold, a chiller, or combinations thereof.

9. The cooling device of claim 1, further comprising at least one pipe connecting the top inlet to the top outlet.

10. The cooling device of claim 9, wherein the at least one pipe comprises brass, copper, zinc, titanium, nickel, silicon, rubber, plastic, or combinations thereof.

11. The cooling device of claim 1, wherein the continuous internal channel is straight, curved, S-shaped, branched, or angular.

12. The cooling device of claim 1, wherein the continuous internal channel is configured to provide direct contact between the active cooling unit and a cooling fluid.

13. The cooling device of claim 1, wherein the passive cooling unit comprises a conventional heatsink pattern, a topology-optimized generative design pattern, or a fractal pattern.

14. The cooling device of claim 1, wherein the passive cooling unit comprises aluminum, copper, chromium, cobalt, gold, iridium, magnesium, molybdenum, rhodium, silicon, silver, sodium, tungsten, zinc, or combinations thereof.

15. The cooling device of claim 1, wherein the cooling device maintains a temperature of less than 50° C. at a pumping power of 10 kW.

16. A method of cooling an optical fiber, comprising:
providing a cooling device which comprises:
an active cooling unit comprising:
a base portion comprising at least one base inlet, at least one base outlet, and an internal channel,
a first intermediate portion comprising an outer surface with grooved indentations configured to hold the optical fiber, a hollow core, at least one intermediate inlet, at least one intermediate outlet, and an internal channel, wherein the first intermediate portion is stackable,
a top portion comprising a hollow core, at least one top inlet, at least one top outlet, and an internal channel,
wherein the internal channels of the base portion, the first intermediate portion, and the top portion are in fluid communication to form a continuous internal channel configured to contain fluid,
wherein the base portion, the first intermediate portion, and the top portion are separable and are connected by the continuous internal channel, and
a passive cooling unit fitted within the hollow core of the first intermediate portion,
applying a pumping power to the optical fiber, and
passing a cooling fluid through the continuous internal channel, thereby cooling the optical fiber.

17. The method of claim 16, wherein the cooling fluid comprises water, glycol, oils, artificial cooling fluids, or combinations thereof.

18. The method of claim 16, wherein the cooling fluid is in direct contact with the cooling device.

19. The method of claim 16, wherein the continuous internal channel is coated with an anti-corrosive material.

20. The method of claim 16, wherein the cooling device further comprises a second intermediate portion comprising an outer surface with grooved indentations, a hollow core, at least one intermediate inlet, at least one intermediate outlet, and an internal channel, wherein the first intermediate portion and the second intermediate portion are stacked such that the internal channel of the first intermediate portion is in fluid communication with the internal channel of the second intermediate portion.

21. The method of claim 20, wherein the cooling device further comprises a second passive cooling unit fitted within the hollow core of the second intermediate portion.

22. The method of claim 16, wherein the base portion, the first intermediate portion, and the top portion each comprise raised features and depressed features that are configured to interlock when the base portion, the first intermediate portion, and the top portion are stacked.

23. The method of claim 16, wherein the cooling device maintains a temperature of less than 50° C. at a pumping power of 10 kW.

24. A fiber laser system with integrated cooling, comprising:
an optical fiber wound around a cooling device which comprises:
an active cooling unit comprising:
a base portion comprising at least one base inlet, at least one base outlet, and an internal channel,
a first intermediate portion comprising an outer surface with grooved indentations configured to hold the optical fiber, a hollow core, at least one intermediate inlet, at least one intermediate outlet, and an internal channel, wherein the first intermediate portion is stackable,
a top portion comprising a hollow core, at least one top inlet, at least one top outlet, and an internal channel,
wherein the internal channels of the base portion, the first intermediate portion, and the top portion are in fluid communication to form a continuous internal channel configured to contain fluid,
wherein the base portion, the first intermediate portion, and the top portion are separable and are connected by the continuous internal channel, and
a passive cooling unit fitted within the hollow core of the first intermediate portion,
a manifold for providing a cooling fluid to the cooling device, and
a power source for providing power to the optical fiber.

25. The fiber laser system with integrated cooling of claim 24, wherein the cooling fluid is in direct contact with the cooling device.

26. The fiber laser system with integrated cooling of claim 24, wherein the continuous internal channel is coated with an anti-corrosive material.

27. The fiber laser system with integrated cooling of claim 24, wherein the cooling device further comprises a second intermediate portion comprising an outer surface with grooved indentations, a hollow core, at least one intermediate inlet, at least one intermediate outlet, and an internal channel, wherein the first intermediate portion and the second intermediate portion are stacked such that the internal channel of the first intermediate portion is in fluid communication with the internal channel of the second intermediate portion.

28. The fiber laser system with integrated cooling of claim 27, wherein the cooling device further comprises a second passive cooling unit fitted within the hollow core of the second intermediate portion.

29. The fiber laser system with integrated cooling of claim 24, wherein the base portion, the first intermediate portion, and the top portion each comprise raised features and depressed features that are configured to interlock when the base portion, the first intermediate portion, and the top portion are stacked.

30. The fiber laser system with integrated cooling of claim 24, wherein the cooling device maintains a temperature of less than 50° C. at a pumping power of 10 kW.
